(19) United States
(12) Patent Application Publication
(10) Pub. No.: US 2018/0233459 A1
(43) Pub. Date: Aug. 16, 2018

(54) MODULE, MODULE MANUFACTURING METHOD, AND PACKAGE

(71) Applicant: NEC Corporation, Tokyo (JP)

(72) Inventor: Makoto Fushimi, Tokyo (JP)

(73) Assignee: NEC Corporation, Tokyo (JP)

(21) Appl. No.: 15/831,478

(22) Filed: Dec. 5, 2017

(30) Foreign Application Priority Data
Feb. 14, 2017 (JP) 2017-025051

(51) Int. Cl. H01L 23/00; H01L 23/498

(52) U.S. Cl. CPC H01L 23/562; H01L 23/49816; H01L 2924/3511; H01L 23/49822; H01L 24/81

(57) ABSTRACT

A first substrate, a second substrate, and a retaining member are included. On the first substrate, a heat-generating part is mounted. The second substrate is connected to the first substrate via a connection member. The retaining member is configured to retain a height between the first substrate and the second substrate and is placed on a surface of the first substrate other than a surface facing the second substrate.

### INCORPORATION BY REFERENCE

This application is based upon and claims the benefit of priority from Japanese patent application No. 2017-025051, filed on Feb. 14, 2017, the disclosure of which is incorporated herein in its entirety by reference.

### TECHNICAL FIELD

The present invention relates to a module, a module manufacturing method, and a package. More specifically, the present invention relates to a module, a module manufacturing method, and a package which decrease warpage.

### BACKGROUND ART

A semiconductor package contains a plurality of components having different thermal expansion coefficients, such as a heat-generating part like an LSI (large scale integrated circuit) and an interposer substrate with the LSI mounted thereon. It is known that a semiconductor package thus containing a plurality of components having different thermal expansion coefficients causes warpage resulting from a difference in thermal expansion coefficient between the components in a reflow process (in reflow soldering) at the time of connection of an interposer substrate to a mother substrate. In particular, a problem is warpage resulting from a difference in thermal expansion coefficient between a mother substrate and an interposer substrate.

A technique for decreasing such warpage is disclosed by Patent Document 1, for example. Patent Document 1 discloses a stiffener which is a frame body with its outer edge located outside the circumference of a multilayer circuit wiring board and its inner edge located inside the circumference of the multilayer circuit wiring board and which has a dent of the same depth as the thickness of the multilayer circuit wiring board on its lower face. To be specific, the stiffener disclosed by Patent Document 1 has the configuration described above and is made of metal whose thermal expansion coefficient is 15% to 30% larger than the thermal expansion coefficient of the multilayer circuit wiring board. Accordingly to Patent Document 1, use of the stiffener described above makes it possible to maintain the flatness of the multilayer circuit wiring board in reflow soldering and securely connect.

Further, a technique for increasing the reliability of connection between an interposer substrate and a mother substrate connecting with the interposer substrate is disclosed by Patent Document 2, for example. Patent Document 2 discloses a semiconductor module which has a first substrate (an interposer substrate) with a semiconductor chip mounted thereon, a second substrate (a mother substrate) with the first substrate mounted therein, and a fixing unit such as a stiffener which holds the semiconductor chip over the first substrate and thereby fixes the semiconductor chip to the second substrate. According to Patent Document 2, the configuration described above enables increase of the connection reliability of the interposer substrate.

Patent Document 1: Japanese Unexamined Patent Application Publication No. JP-A 2004-356142

Patent Document 2: Japanese Unexamined Patent Application Publication No. JP-A 2004-207415

As described in Patent Document 1, various techniques for inhibiting warpage which occurs at the time of soldering are known, but there is a fear that more warpage than expected occurs depending on a condition at the time of soldering. When more warpage than expected thus occurs, solder balls connecting the interposer substrate with the mother substrate stretch or collapse depending on the condition of warpage of the interposer substrate. As a result, there is a fear that stretch of the solder balls causes decrease of joint strength or contact of the neighboring collapsed solder balls causes a short circuit. Moreover, depending on the condition at the time of soldering, the solder balls may collapse more than expected due to the weight of the interposer substrate and the neighboring solder balls come in contact with each other and cause a short circuit.

Thus, a problem is a fear of, at the time of connection of the interposer substrate with the mother substrate, occurrence of joint failure, short circuit and so on due to stretch and collapse of the solder balls. In other words, a problem is that it is difficult to decrease a probability of occurrence of a problem at the time of connection of the interposer substrate with the mother substrate. Moreover, such a problem cannot be solved by the technique disclosed by Patent Document 2, which is joining the stiffener after connecting the interposer substrate with the mother substrate.

### SUMMARY OF THE INVENTION

Accordingly, an object of the present invention is to provide a module, a module manufacturing method, and a package which solve the problem that it is difficult to decrease a probability of occurrence of a problem at the time of connection of the interposer substrate with the mother substrate.

In order to achieve the object, a module as an aspect of the present invention includes:

a first substrate with a heat-generating part mounted thereon;

a second substrate connected to the first substrate via a connection member; and

a retaining member configured to retain a height between the first substrate and the second substrate and is placed on a surface of the first substrate other than a surface facing the second substrate.

Further, a module manufacturing method as another aspect of the present invention includes:

connecting a retaining member to a surface of a first substrate other than a surface facing a second substrate, a heat-generating part being mounted on the first substrate, the second substrate being connected to the first substrate, the retaining member retaining a height between the first substrate and the second substrate; and connecting the first substrate to the second substrate.

Further, a package as another aspect of the present invention includes:

a first substrate with a heat-generating part mounted thereon; and

a retaining member configured to retain a height between the first substrate and a second substrate connected to the first substrate, and placed on a surface of the first substrate other than a surface facing the second substrate.

With the configurations as described above, the present invention can provide a module, a module manufacturing method, and a package which solve the problem that it is difficult to decrease a probability of occurrence of a problem at the time of connection of the interposer substrate with the mother substrate.

### BRIEF DESCRIPTION OF DRAWINGS

FIG. 1 is a plan view showing an example of a configuration of a semiconductor module according to a first exemplary embodiment of the present invention;

FIG. 2 is a section view showing an example of a configuration of the semiconductor module taken on line A-A of FIG. 1;

FIG. 3 is a section view showing an example of a configuration of the semiconductor package and a mother substrate configuring the semiconductor module shown in FIG. 2;

FIG. 4 is a perspective view showing an example of a configuration of a retaining-member-equipped stiffener shown in FIG. 1;

FIG. 5 is a flowchart showing an example of a flow at the time of manufacture of the semiconductor module according to the first exemplary embodiment of the present invention; FIG. 6 is a section view showing an example of another configuration of the semiconductor module according to the first exemplary embodiment;

FIG. 7 is a section view showing an example of another configuration of the semiconductor module according to the first exemplary embodiment;

FIG. 8 is a perspective view showing an example of another configuration of the retaining-member-equipped stiffener;

FIG. 9 is a section view showing an example of a configuration of a semiconductor module according to a second exemplary embodiment of the present invention; and

FIG. 10 is a section view showing an example of a configuration of a semiconductor package according to the second exemplary embodiment of the present invention.

### EXEMPLARY EMBODIMENT

### First Exemplary Embodiment

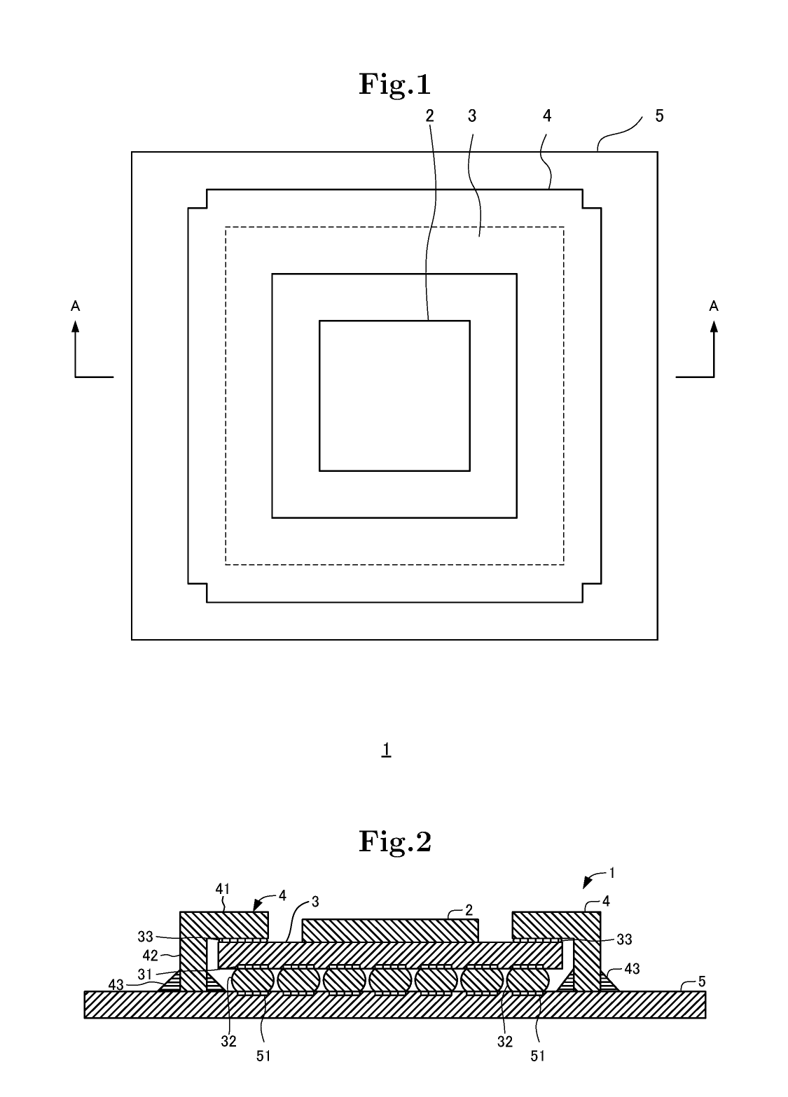

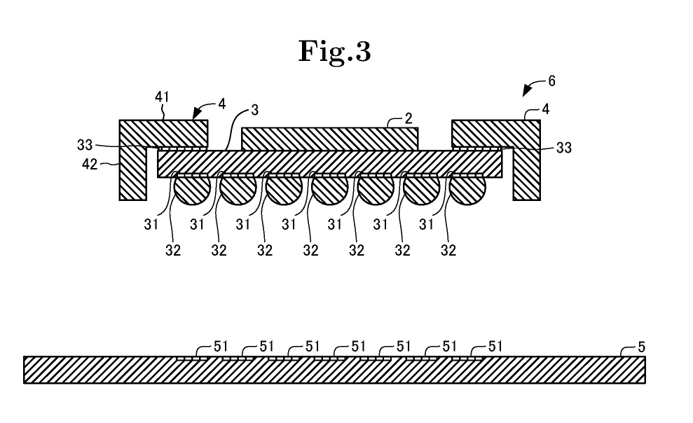

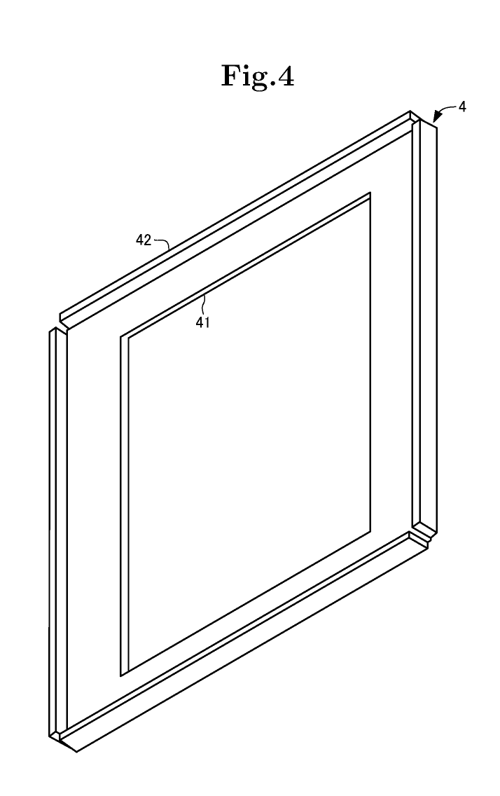

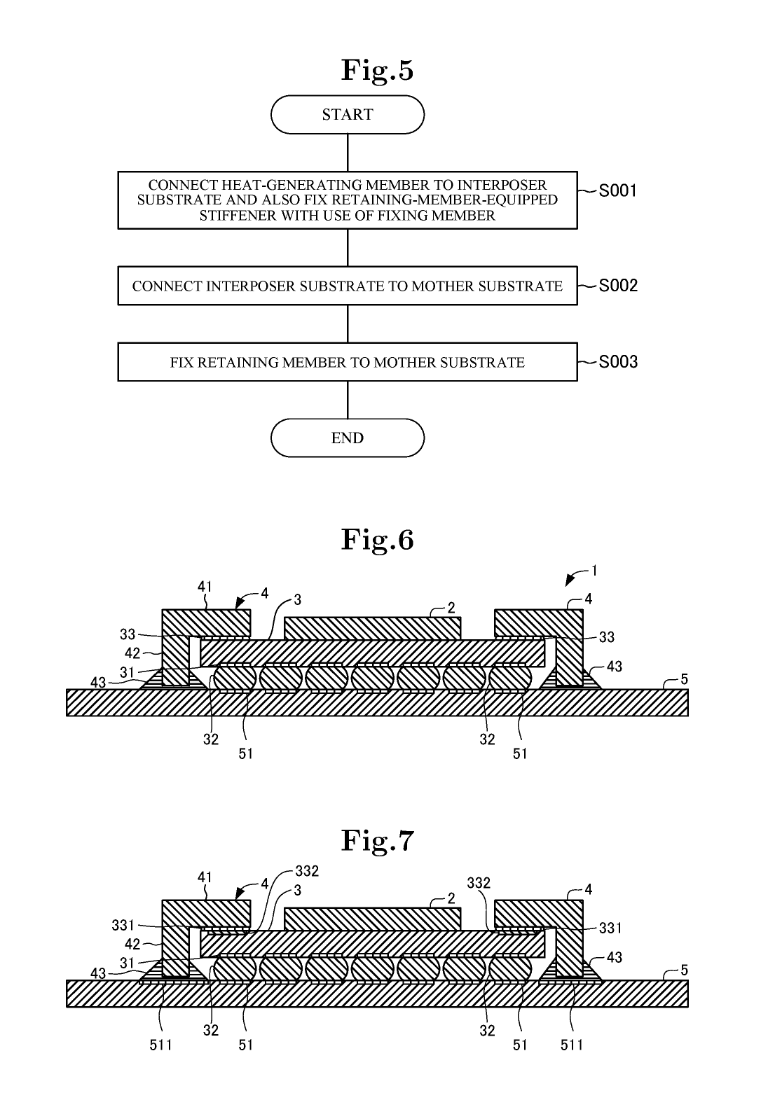

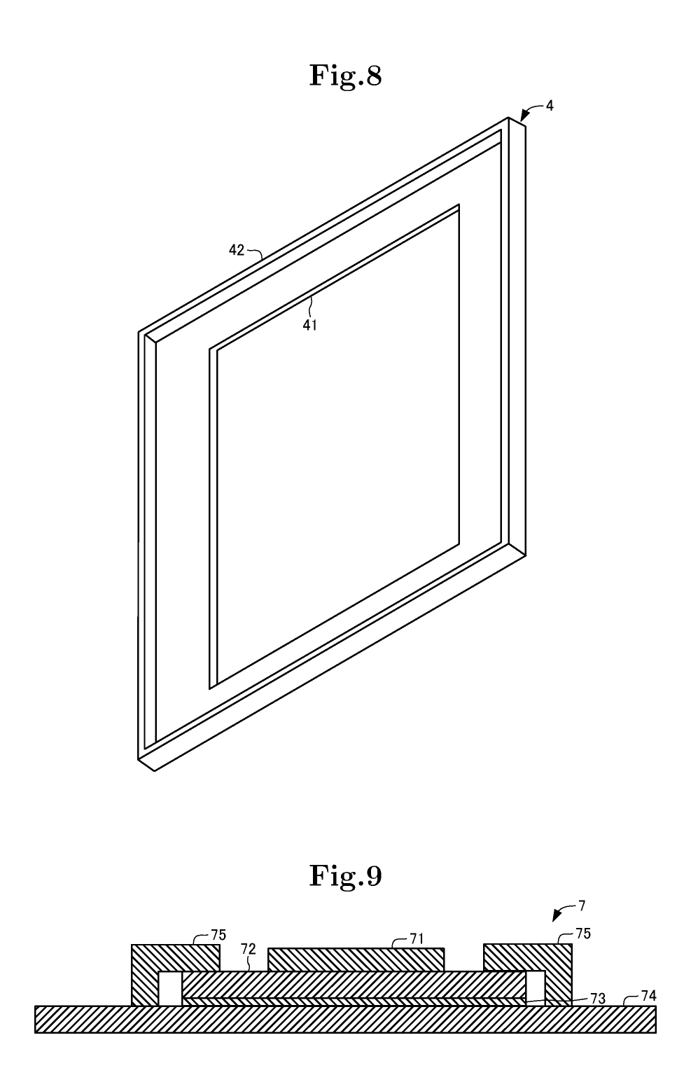

A first exemplary embodiment of the present invention will be described with reference to FIGS. 1 to 8. FIG. 1 is a plan view showing an example of a configuration of a semiconductor module 1. FIG. 2 is a section view showing an example of a configuration of the semiconductor module 1 taken on line A-A of FIG. 1. FIG. 3 is a section view showing an example of a configuration of a semiconductor package 6 and a mother substrate 5 configuring the semiconductor module 1. FIG. 4 is a perspective view showing an example of a configuration of a retaining-member-equipped stiffener 4. FIG. 5 is a flowchart showing an example of a flow at the time of manufacture of the semiconductor module 1. FIGS. 6 and 7 are section views showing examples of other configurations of the semiconductor module 1. FIG. 8 is a perspective view showing an example of another configuration of the retaining-member-equipped stiffener 4.

In the first exemplary embodiment, the semiconductor module 1 having the retaining-member-equipped stiffener 4 will be described. As will described later, the retaining-member-equipped stiffener 4 in this exemplary embodiment has a retaining member 42. The retaining member 42, at the time of connection of an interposer substrate 3 with the mother substrate 5 in a reflow process or the like, for example, makes a lower end side (an end on the side of the mother substrate 5) of the retaining member 42 abut the mother substrate 5 and thereby retains a height between the interposer substrate 3 and the mother substrate 5. Consequently, excessive proximity of the interposer substrate 3 and the mother substrate 5 can be inhibited, and occurrence of a problem such as a short circuit due to the collapse of a solder ball resulting from warpage of the interposer substrate 3 or the like can be inhibited.

With reference to FIGS. 1 and 2, the semiconductor module 1 (a module) in this exemplary embodiment has a heat-generating part 2, the interposer substrate 3 (a first substrate), the retaining-member-equipped stiffener 4, and the mother substrate 5 (a second substrate). For example, as shown in FIG. 3, the semiconductor module 1 is manufactured by connecting a semiconductor package 6 (a package) to the mother substrate 5. The semiconductor package 6 is manufactured by connecting the heat-generating part 2 to the interposer substrate 3 and fixing the retaining-member-equipped stiffener 4.

The heat-generating part 2 is a member which generates heat, such as an LSI (large scale integrated circuit). A major component of the heat-generating part 2 is silicon, for example. The heat-generating part 2 is connected (mounted) onto a center portion of the interposer substrate 3 by wire bonding, flop chip bonding, or the like (see FIG. 2 and so on).

The interposer substrate 3 is a substrate such as a glass epoxy substrate (may be a substrate having a different composition from the illustrated one). The interposer substrate 3 has a substantially rectangular shape in planar view, for example.

On one surface of the interposer substrate 3, which is on a side connected to the mother substrate 5, electric pads 31 are placed so as to form a grid, for example. On the electric pads 3 placed so as to form a grid, solder balls 32 (metal balls) serving as connection members are formed, respectively. The solder ball 32 may have any size (for example, approximately 0.5 mm in diameter).

Further, on the other side of the interposer substrate 3, which is on the opposite side from the side with the solder balls 32 formed thereon, the heat-generating part 2 is connected, and also the retaining-member-equipped stiffener 4 is fixed with the use of a fixing member 33 such as an adhesive (any adhesive). In other words, on a surface of the interposer substrate 3 with the heat-generating part 2 connected thereto, which is a surface other than the surface facing the mother substrate 5, the retaining-member-equipped stiffener 4 is fixed. For example, as shown in FIG. 1, the heat-generating part 2 is connected to a center portion of the interposer substrate 3, and the retaining-member-equipped stiffener 4 is fixed so as to cover a circumferential portion.

The retaining-member-equipped stiffener 4 is a reinforcement member made of metal such as copper. The retaining-member-equipped stiffener 4 is fixed to the interposer substrate 3, thereby inhibiting warpage of the interposer substrate 3 and also keeping a height between the interposer substrate 3 and the mother substrate 5 with the use of the retaining member 42 of the retaining-member-equipped stiffener 4.

The retaining-member-equipped stiffener 4 is formed by a stiffener part 41 and the retaining member 42, for example, as shown in FIG. 4.

The stiffener part 41 is a part fixed to the interposer substrate 3 by the fixing member 33 and is a part which is equivalent to a general stiffener. The stiffener part 41, as shown in FIGS. 1 and 2, has a rectangular shape having a quadrangular through hole for inserting the heat-generating part 2 at the center portion in planar view. The stiffener part 41 is fixed to the interposer substrate 3 by the fixing member 33 such as an adhesive, thereby reinforcing the interposer substrate 3, and inhibiting or decreasing warpage of the interposer substrate 3 or the like which may occur at the time of reflow. Moreover, the stiffener part 41 has the through hole as described above (that is, the stiffener part 41 is opened), so that the heat-generating part 2 connected to the interposer substrate 3 can directly come in contact with a cooling mechanism such as a heat sink not via the retaining-member-equipped stiffener 4. In other words, the retaining-member-equipped stiffener 4 makes it possible to directly cool the heat-generating member 2 in a state where the retaining-member-equipped stiffener 4 is fixed to the interposer substrate 3.

The retaining member 42 is a region formed by extending the stiffener part 41. For example, the retaining member 42 is formed by bending a portion formed by extending the stiffener part 41, for example, 90 degrees (may be any angle other than the illustrated one) toward the interposer substrate 3 (toward the mother substrate 5) (see FIG. 4). By making the lower end side of the retaining member 42 abut the mother substrate 5, the retaining member 42 retains a height between the interposer substrate 3 and the mother substrate 42. Moreover, the retaining-member-equipped stiffener 4 has the retaining member 42, so that the retaining-member-equipped stiffener 4 includes a bent structure. Consequently, the reinforcement member has a structure which is more robust over bending than in a case where a reinforcement member is composed of only the stiffener part 41 (in a case where a reinforcement member is a plat plate) (that is, the reinforcement member is more robust over warpage than a reinforcement member which is a flat plate).

An end on a lower end side (on the side of the mother substrate 5) of the retaining member 42 is, for example, located lower than the surface of the interposer substrate 3 on the side of the mother substrate 5 and located higher than an end of the solder ball 32 on the side of the mother substrate 5. That is, a place where the retaining member 42 abuts the mother substrate 5 is, for example, located lower than the interposer substrate 3 and higher than the lower end of the solder ball 32. For example, in a case where the diameter of the solder ball 32 is 0.5 mm, the end on the lower end side (on the side of the mother substrate 5) of the retaining member 42 is adjusted so as to be located about 0.1 mm higher than the end on the lower end side of the solder ball 32. By thus forming the retaining member 42 in accordance with the size of the solder ball, it is possible to retain a height between the interposer substrate 3 and the mother substrate 5 without disturbing connection of the interposer substrate 3 with the mother substrate 5. Meanwhile, the end on the lower end side of the retaining member 42 may be a position other than that shown as an example above.

Further, the retaining member 42 (the retaining-member-equipped stiffener 4) can be fixed to the mother substrate 5 with the use of a second connection member 43 such as solder. A timing for fixing the retaining member 42 to the mother substrate 5 may be any timing. For example, the retaining member 42 may be fixed to the mother substrate 5 together with the interposer substrate 3 in a reflow process to connect the interposer substrate 3 to the mother substrate 5. Otherwise, the retaining member 42 may be fixed to the mother substrate 5 after connecting the interposer substrate 3 to the mother substrate 5. Fixing the retaining member 42 to the mother substrate 5 enables increase of robustness over bending.

The mother substrate 5 is a substrate such as a glass epoxy substrate (may have a composition other than the illustrated one). The mother substrate 5 has a substantially rectangular shape in planar view, for example.

On the mother substrate 5, the electric pads 51 are placed so as to form a grid, for example. The mother substrate 5 is connected with the interposer substrate 3 in a state where the electric pads 51 placed so as to form a grid abut the solder balls 32 formed on the interposer substrate 3, respectively. As described above, the retaining-member-equipped stiffener 4 can be fixed to the mother substrate 5.

The above is an example of the configuration of the semiconductor module 1. As described above, the heat-generating part 2, the interposer substrate 3, and the retaining-member-equipped stiffener 4 configure the semiconductor package 6. Therefore, it can also be said that the semiconductor module 1 includes the semiconductor package 6 and the mother substrate 5, for example.

Next, with reference to FIG. 5, an example of a flow at the time of manufacture of the semiconductor module 1 as illustrated above will be described.

With reference to FIG. 5, onto a surface of the interposer substrate 3, which is on the opposite side from a surface with the solder balls 32 formed thereon, the heat-generating part 2 is connected by wire boding or the like. Moreover, on a surface of the interposer substrate 3, which is the same as the surface with the heat-generating member 2 connected thereto, the retaining-member-equipped stiffener 4 is fixed by the fixing member 33 such as an adhesive or the like (step S001). Thus, the semiconductor package 6 is manufactured as shown in FIG. 3.

Subsequently, in the reflow process or the like, the semiconductor package 6 (the interposer substrate 3) is connected to the mother substrate 5 (step S002). As described above, the semiconductor package 6 has the retaining-member-equipped stiffener 4 having the retaining member 42. Due to such a configuration, at the time of connection of the interposer substrate 3 with the mother substrate 5, the lower end side of the retaining member 42 abuts on the mother substrate 5, thereby retaining a height between the interposer substrate 3 and the mother substrate 5.

Further, the retaining member 42 is fixed on the mother substrate 5 (step S003). The operation at step S003 may be performed simultaneously with the operation at step S002. In other words, the retaining member 42 can be configured to be fixed onto the mother substrate 5 in the reflow process.

The above is an example of the flow of manufacture of the semiconductor module 1.

Thus, the semiconductor module 1 in this exemplary embodiment has the retaining-member-equipped stiffener 4 having the retaining member 42. With such a configuration, it is possible to, at the time of connection of the interposer substrate 3 to the mother substrate 5, make the lower end portion of the retaining member 42 abut on the mother substrate 5 and thereby retain a height between the interposer substrate 3 and the mother substrate 5. As a result, excessive proximity of the interposer substrate 3 and the mother substrate 5 can be inhibited, and occurrence of a problem such as a short circuit due to the collapse of the solder balls resulting from the warpage of the interposer substrate or the like can be inhibited.

Further, as in the case of the retaining-member-equipped stiffer 4, it is possible to, by adding a bent structure to a stiffener, make the stiffener more robust over bending than in the case of using a flat plate reinforce member. In other words, the retaining-member-equipped stiffener 4 in this exemplary embodiment further enables inhibition of warpage at the time of reflow.

With reference to FIG. 5, a case where the lower end side of the retaining member 42 abuts on the mother substrate 5 has been illustrated. However, for example, as shown in FIG. 6, in a case where excessive warpage or the like has not occurred in the interposer substrate 3, a situation that the lower end side of the retaining member 42 does not abut on the mother substrate 5 can also be assumed. In other words, in order to inhibit excessive proximity of the interposer substrate 3 and the mother substrate 5, the retaining member 42 may not abut on the mother substrate 5 depending on a height between the interposer substrate 3 and the mother substrate 5.

Further, as shown in FIG. 7, the semiconductor module 1 may be configured so that the retaining-member-equipped stiffener 4 electrically connects the interposer substrate 3 with the mother substrate 5.

To be specific, with reference to FIG. 7, in the case of electrically connecting the interposer substrate 3 with the mother substrate 5, the retaining-member-equipped stiffener 4 is fixed with the interposer substrate 3 by using an electrically conductive member 331 instead of the fixing member 33 when compared with FIG. 2. The electrically conductive member 331 is a member such as solder having a characteristic of passing electricity. The electrically conductive member 331 may be an electrically conductive adhesive other than solder, for example.

Further, on the interposer substrate 3, electric pads 332 are formed at positions (at least part thereof) where the electrically conductive members 331 are formed. Moreover, on the mother substrate 5, electric pads 511 are formed at places (at least part thereof) where the retaining member 42 abuts (places where the second connection members 43 are formed).

By configuring the semiconductor module 1 as described above, for example, it is possible to electrically connect the interposer substrate 3 with the mother substrate 5 with the use of the retaining-member-equipped stiffener 4.

It is desired that the electrically conductive member 331 has a higher melting point than solder forming the solder ball 32. To be specific, for example, for the electrically conductive member 331, it is desired to use high-melting-point solder which has a higher melting point than the solder used for forming the solder ball 32. With such a configuration, it is possible to, for example, prevent the electrically conductive member 331 from melting when connecting the interposer substrate 3 with the mother substrate 5. The melting point of the solder can be regulated by regulating the composition of the solder.

Further, in the case of electrically connecting the interposer substrate 3 with the mother substrate 5, only the retaining-member-equipped stiffener 4 may have a function as a power supply. In this case, it is possible to reduce the number of the solder balls 32.

Further, in this exemplary embodiment, a case where the retaining-member-equipped stiffener 4 fixed onto the surface with the heat-generating part 2 connected thereto of the interposer substrate 3 has the retaining member 42 has been described. However, the retaining member 42 may be placed in a place other than the one illustrated in this exemplary embodiment. The retaining member 42 may be fixed onto a side face of the interposer substrate 3. Moreover, in this exemplary embodiment, by making the lower end side of the retaining member 42 abut on the mother substrate 5, the retaining member 42 retains a height between the interposer substrate 3 and the mother substrate 5. However, the retaining member 42 may be configured to retain a height between the interposer substrate 3 and the mother substrate 5 by a method other than the one illustrated above. For example, the retaining member 42 may be configured to be engaged with another region not shown in the drawings, thereby retaining a height between the interposer substrate 3 and the mother substrate 5.

Further, the shape of the retaining-member-equipped stiffener 4 is not limited to the one illustrated in this exemplary embodiment. For example, as shown in FIG. 8, the stiffener 4 may be formed of the stiffener 41 and the retaining member 42 serving as a frame shape surrounding the four sides. The shape as shown in FIG. 8 can be formed, for example, by cutting and processing a sheet metal configuring the retaining-member-equipped stiffener 4. In other words, the stiffener 4 may have a structure that a plate-like member having an opening is cut and processed into a U-shaped region and the interposer substrate 3 is bonded to the U-shaped region.

### Second Exemplary Embodiment

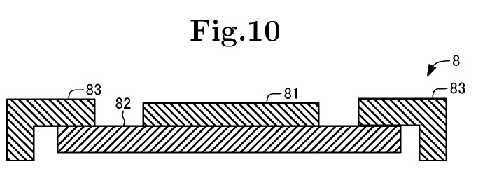

Next, with reference to FIGS. 9 and 10, a second exemplary embodiment of the present invention will be described. FIG. 9 is a section view showing an example of a configuration of a module 7. FIG. 10 is a section view showing an example of a configuration of a package 8.

In the second exemplary embodiment, the outline of the configurations of the module 7 and the package 8 will be described. First, the module 7 will be described with reference to FIG. 9.

With reference to FIG. 9, the module 7 includes a heat-generating part 71, a first substrate 72, a connection member 73, a second substrate 74, and a retaining member 75.

On the first substrate 72, the heat-generating part 71 is mounted. Moreover, the first substrate 72 is connected with the second substrate 74 via the connection member 73.

Further, on a surface of the first substrate 72 other than a surface facing the second substrate 74, the retaining member 75 that retains a height between the first substrate 72 and the second substrate 74 is placed. FIG. 9 illustrates a case where the retaining member 75 is placed on a surface of the first substrate 72 which is the same as the surface with the heat-generating member 71 mounted thereon.

Thus, the module 7 in this exemplary embodiment has the retaining member 75. With such a configuration, at the time of connection of the first substrate 72 with the second substrate 74, a height between the first substrate 72 and the second substrate 74 can be retained by the retaining member 75. As a result, excessive proximity of the first substrate 72 and the second substrate 74 at the time of connection of the first substrate 72 with the second substrate 74 can be inhibited, and a probability of occurrence of a problem such as a short circuit resulting from the collapse of the connection member 73 at the time of connection of the first substrate 72 with the second substrate 74 can be decreased.

Further, a module manufacturing method for manufacturing the module 7 described above is a method which includes connecting the first substrate 72 to the second substrate 74 after connecting the retaining member 75 that retains a height between the first substrate 72 and the second substrate 74 to a surface of the first substrate 72 with the heat-generating part 71 connected thereto, which is a surface other than a surface facing the second substrate 74 connecting with the first substrate 72.

An invention of a module manufacturing method having the abovementioned configuration has the same action as the abovementioned module, and therefore, can also achieve the object of the present invention described above.

Next, with reference to FIG. 10, the package 8 will be described.

With reference to FIG. 10, the package 8 includes a heat-generating part 81, a first substrate 82, and a retaining member 83.

On the first substrate 82, the heat-generating part 81 is mounted.

Further, a retaining member 83 that retains a height between the first substrate 82 and a second substrate, which is not shown in the drawing, is placed on a surface of the first substrate 82 other than a surface facing the second substrate connecting with the first substrate 82. FIG. 10 illustrates a case where the retaining member 83 is placed on a surface of the first substrate 82, which is the same as the surface with the heat-generating part 81 mounted thereon.

Thus, the package 8 in this exemplary embodiment has the retaining member 83. With such a configuration, it is possible to, when connecting the first substrate 82 with the second substrate, retain a height between the first substrate 82 and the second substrate by using the retaining member 83. As a result, it is possible to, when connecting the first substrate 82 with the second substrate, inhibit excessive proximity of the first substrate 82 and the second substrate, and it is possible to decrease a probability of occurrence of a problem at the time of connection.

### <Supplementary Notes>

The whole or part of the exemplary embodiments disclosed above can be described as the following supplementary notes. Below, the outline of a module and so on according to the present invention will be described. Meanwhile, the present invention is not limited to the following configurations.

### (Supplementary Note 1)

A module comprising:

a first substrate with a heat-generating part mounted thereon;

a second substrate connected to the first substrate via a connection member; and

a retaining member configured to retain a height between the first substrate and the second substrate, the retaining member being placed on a surface of the first substrate other than a surface facing the second substrate.

### (Supplementary Note 2)

The module according to Supplementary Note 1, wherein the retaining member is formed in accordance with a size of a metal ball previously placed on the first substrate, the metal ball serving as the connection member.

### (Supplementary Note 3)

The module according to Supplementary Note 1 or 2, wherein the retaining member is fixed to the second substrate to connect the first substrate with the second substrate.

### (Supplementary Note 4)

The module according to any of Supplementary Notes 1 to 3, wherein the retaining member is configured to electrically connect the first substrate with the second substrate.

### (Supplementary Note 5)

The module according to any of Supplementary Notes 1 to 4, wherein: the first substrate and the retaining member are connected by an electrically conductive member; and

the electrically conductive member is a member having a higher melting point than solder serving as the connection member.

### (Supplementary Note 6)

The module according to Supplementary Note 5, wherein the electrically conductive member is a high-melting-point solder having a higher melting point than the solder serving as the connection member.

### (Supplementary Note 7)

The module according to any of Supplementary Notes 1 to 6, wherein the retaining member is formed by an extension of a stiffener placed on a side of a surface of the first substrate with the heat-generating part mounted thereon.

### (Supplementary Note 8)

The module according to Supplementary Note 7, wherein the retaining member is a member made by bending the extension of the stiffener toward the first substrate.

### (Supplementary Note 9)

A module manufacturing method, comprising:

connecting a retaining member to a surface of a first substrate other than a surface facing a second substrate, a heat-generating part being mounted on the first substrate, the second substrate being connected to the first substrate, the retaining member retaining a height between the first substrate and the second substrate; and

connecting the first substrate to the second substrate.

### (Supplementary Note 10)

The module manufacturing method according to Supplementary Note 9, comprising

connecting the first substrate to the second substrate and fixing the retaining member to the second substrate.

### (Supplementary Note 11)

The module manufacturing method according to Supplementary Note 9, comprising:

connecting the first substrate to the second substrate by using a connection member previously formed on the first substrate.

### (Supplementary Note 12)

The module manufacturing method according to Supplementary Note 9, wherein the retaining member is formed by an extension of a stiffener placed on a side of a surface of the first substrate with the heat-generating part mounted thereon.

### (Supplementary Note 13)

A package comprising:

a first substrate with a heat-generating part mounted thereon; and

a retaining member configured to retain a height between the first substrate and a second substrate, the retaining member being placed on a surface of the first substrate other than a surface facing the second substrate, the second substrate being connected to the first substrate.

### (Supplementary Note 14)

The package according to Supplementary Note 13, wherein:

the first substrate is configured to be connected to the second substrate via a connection member; and

the retaining member is formed in accordance with a size of a metal ball previously placed on the first substrate, the metal ball serving as the connection member.

### (Supplementary Note 15)

The package according to Supplementary Note 13, wherein the retaining member is fixed to the second substrate to connect the first substrate with the second substrate.

### (Supplementary Note 16)

The package according to Supplementary Note 13, wherein the retaining member is configured to electrically connect the first substrate with the second substrate.

### (Supplementary Note 17)

The package according to Supplementary Note 13, wherein:

the first substrate and the retaining member are connected by an electrically conductive member; and

the electrically conductive member is a member having a higher melting point than solder serving as the connection member.

### (Supplementary Note 18)

The package according to Supplementary Note 17, wherein the electrically conductive member is a high-melting-point solder having a higher melting point than the solder serving as the connection member.

### (Supplementary Note 19)

The package according to Supplementary Note 13, wherein the retaining member is formed by an extension of a stiffener placed on a side of a surface of the first substrate with the heat-generating part mounted thereon. connection member.

### (Supplementary Note 20)

The package according to Supplementary Note 19, wherein the retaining member is a member made by bending the extension of the stiffener toward the first substrate.

Although the present invention has been described above with reference to the respective exemplary embodiments, the present invention is not limited to the exemplary embodiments described above. The configurations and details of the present invention can be altered and changed in various manners that can be understood by one skilled in the art without the scope of the present invention.

### DESCRIPTION OF REFERENCE NUMERALS

1 semiconductor module
2 heat-generating part
3 interposer substrate
31 electric pad
32 solder ball
33 fixing member
331 electrically conductive member
332 electric pad
4 retaining-member-equipped stiffener
41 stiffener part
42 retaining member
43 second connection member
5 mother substrate
51 electric pad
511 electric pad
6 semiconductor package
7 module
71 heat-generating part
72 first substrate
73 connection member
74 second substrate
75 retaining member
8 package
81 heat-generating part
82 first substrate
83 retaining member

1. A module comprising:
a first substrate with a heat-generating part mounted thereon;
a second substrate connected to the first substrate via a connection member; and
a retaining member configured to retain a height between the first substrate and the second substrate, the retaining member being placed on a surface of the first substrate other than a surface facing the second substrate.

2. The module according to claim 1, wherein the retaining member is formed in accordance with a size of a metal ball previously placed on the first substrate, the metal ball serving as the connection member.

3. The module according to claim 1, wherein the retaining member is fixed to the second substrate to connect the first substrate with the second substrate.

4. The module according to claim 1, wherein the retaining member is configured to electrically connect the first substrate with the second substrate.

5. The module according to claim 1, wherein:
the first substrate and the retaining member are connected by an electrically conductive member; and
the electrically conductive member is a member having a higher melting point than solder serving as the connection member.

6. The module according to claim 5, wherein the electrically conductive member is a high-melting-point solder having a higher melting point than the solder serving as the connection member.

7. The module according to claim 1, wherein the retaining member is formed by an extension of a stiffener placed on a side of a surface of the first substrate with the heat-generating part mounted thereon.

8. The module according to claim 7, wherein the retaining member is a member made by bending the extension of the stiffener toward the first substrate.

9. A module manufacturing method, comprising:
connecting a retaining member to a surface of a first substrate other than a surface facing a second substrate, a heat-generating part being mounted on the first substrate, the second substrate being connected to the first substrate, the retaining member retaining a height between the first substrate and the second substrate; and
connecting the first substrate to the second substrate.

10. The module manufacturing method according to claim 9, comprising
connecting the first substrate to the second substrate and fixing the retaining member to the second substrate.

11. The module manufacturing method according to claim 9, comprising:
connecting the first substrate to the second substrate by using a connection member previously formed on the first substrate.

12. The module manufacturing method according to claim 9, wherein the retaining member is formed by an extension of a stiffener placed on a side of a surface of the first substrate with the heat-generating part mounted thereon.

13. A package comprising:
a first substrate with a heat-generating part mounted thereon; and
a retaining member configured to retain a height between the first substrate and a second substrate, the retaining member being placed on a surface of the first substrate other than a surface facing the second substrate, the second substrate being connected to the first substrate.

14. The package according to claim 13, wherein:
the first substrate is configured to be connected to the second substrate via a connection member; and
the retaining member is formed in accordance with a size of a metal ball previously placed on the first substrate, the metal ball serving as the connection member.

15. The package according to claim 13, wherein the retaining member is fixed to the second substrate to connect the first substrate with the second substrate.

16. The package according to claim 13, wherein the retaining member is configured to electrically connect the first substrate with the second substrate.

17. The package according to claim 13, wherein:
the first substrate and the retaining member are connected by an electrically conductive member; and
the electrically conductive member is a member having a higher melting point than solder serving as the connection member.

18. The package according to claim 17, wherein the electrically conductive member is a high-melting-point solder having a higher melting point than the solder serving as the connection member.

19. The package according to claim 13, wherein the retaining member is formed by an extension of a stiffener placed on a side of a surface of the first substrate with the heat-generating part mounted thereon.

20. The package according to claim 19, wherein the retaining member is a member made by bending the extension of the stiffener toward the first substrate.
